(19) United States
(12) Patent Application Publication
(10) Pub. No.: US 2009/0072911 A1
(43) Pub. Date: Mar. 19, 2009

(54) SIGNAL GENERATING APPARATUS AND METHOD THEREOF

(76) Inventors: Ling-Wei Ke, Hsin-Chu Hsien (TW); Tai-Yuan Yu, Taoyuan County (TW); Hsin-Hung Chen, Miaoli County (TW); Tser-Yu Lin, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/855,161

(22) Filed: Sep. 14, 2007

(51) Int. Cl. H03L 7/087; H03L 7/08; H03L 7/085

(52) U.S. Cl. 331/16

(57) ABSTRACT

A signal generating apparatus is disclosed. The signal generating apparatus includes a phase-locked loop device for generating a synthesized signal, wherein the phase-locked loop device includes a phase detector, a charge pump device, a filtering device, a controllable oscillator, and a switch device coupled to the controllable oscillator for selectively coupling the controllable oscillator to the filtering device or a tuning reference signal; a calibration controller generates a tuning reference signal and controls the switch device; and a first calibrator tunes the controllable oscillator into a predetermined sub-band according to a reference oscillating signal and a synthesized signal when the switch device couples the controllable oscillator to the tuning reference signal of the calibration controller.

### BACKGROUND

The present invention relates to a signal generating apparatus, and more particularly to a phase-locked loop synthesizer with sub-band and loop gain calibration devices, and a method thereof.

An electronic system or circuit always utilizes a frequency synthesizer to synchronize a system, where the frequency synthesizer always includes a frequency locking circuit, such as a phase-locked loop (PLL) circuit, to lock a specific signal to a specific frequency. As the system speed rapidly increases, it is difficult to maintain the locking speed of the frequency locking circuit. In fact, the locking speed of the frequency locking circuit is generally limited by the frequency of a reference clock signal. Therefore, it is problematic to apply a traditional frequency locking circuit to a high speed hopping system with high reference clock signal frequency.

Furthermore, the loop bandwidth BW of the PLL circuit is maintained as stably as possible within a predetermined range of output frequency of the PLL circuit. Referring to FIG. 1, FIG. 1 is a diagram illustrating a related art PLL circuit 10. The PLL circuit 10 contains a phase detector 11, a charge pump 12, a loop filter 13, a voltage controlled oscillator (VCO) 14, and a frequency divider 15. The phase detector 11 receives a reference signal f_{R} and a feedback signal f_{b}, and compares the phase of these two signals to generate two signals UP and DOWN, which together represent the phase difference Δ between these two signals. The UP and DOWN signals are transmitted to the charge pump 12 which generates a control current I_{C} accordingly. When the charge pump 12 receives the UP signal, the charge pump 12 sources a current having a magnitude of I_{source} to the loop filter 13. When the charge pump 12 receives the DOWN signal, the charge pump 12 sinks a current having a magnitude of Iₛᵢₙₖ from the loop filter 13. Typically, I_{source} equals to Iₛᵢₙₖ. The loop filter 13 suppresses the high frequency components of the control current I_{C} and then outputs a VCO control voltage Vₜ to control the VCO 14. The output frequency f_{PLL} of the VCO 14 on one hand serves as the output signal of the PLL circuit 10, and on the other hand is divided to form the feedback signal f_{b} through the frequency divider 15. The feedback signal f_{b} is then fed back to the phase detector 11.

It is well known that a loop bandwidth BW of a PLL circuit 10 is proportional to the square root of the product of the VCO gain K_{VCO} and a charge pump gain K_{CP}. That is, W ∝ (K_{VCO}×K_{CP})^{1/2}. Generally, the definition of the VCO gain K_{VCO} is the ratio of the frequency variance of the output signal f_{PLL} to the variance of the VCO control voltage Vₜ. The VCO gain K_{VCO} is also referred to as tuning sensitivity. The charge pump gain K_{CP} is defined to be the value of I_{source} (or Iₛᵢₙₖ).

When the PLL circuit 10 is implemented within an integrated circuit, the characteristics of the VCO gain K_{VCO} are usually dependent on the VCO control voltage Vₜ. The VCO gain K_{VCO} cannot be regarded as a constant value within a predetermined range R of the VCO control voltage Vₜ. Therefore, the loop bandwidth BW varies as a function of the VCO control voltage Vₜ, despite the charge pump gain K_{CP} being almost constant. As a result, the loop bandwidth BW varies greatly within a predetermined range R of the VCO control voltage Vₜ such that the performance of the PLL circuit varies broadly. In order to improve the performance of the PLL circuit 10, it is desirable to provide a PLL with compensated loop bandwidth such that the variation of loop bandwidth can be reduced. Furthermore, in a multi-band communication system, the PLL circuit 10 needs to generate different frequency bands. However, for the sake of process variation, the VCO 14 of the PLL circuit 10 does not always oscillate at the required band, and therefore an effective scheme to calibrate the sub-band of the VCO 14 is also necessary. For the full description of related techniques, U.S. Pat. Nos. 6,388,536B1, 6,806,781B2, 6,597,249B2, 710,3337B2, 7,064,591B1, 5,648,744, 6,853,261, 5,631,587, 6,731,145B1, 5,625,325, 6,583,675B2, 6,998,922B2, 7,068,112B2, 6,724,265B2, 2002/0039050 A1, and 2006/0049878 A1 can be referred to.

### SUMMARY OF THE INVENTION

Therefore, one of the objectives of the present invention is to provide a phase-locked loop synthesizer with sub-band and loop gain calibration devices, and a method thereof.

According to an embodiment of the present invention, a signal generating apparatus is disclosed. The signal generating apparatus comprises a phase-locked loop device, a calibration controller, and a first calibrator. The phase-locked loop device generates a synthesized signal, and the phase-locked loop device comprises a phase detector coupled to a reference oscillating signal for generating a detected signal according to the reference oscillating signal and the synthesized signal; a charge pump device coupled to the phase detector, for generating a control signal according to the detected signal; a filtering device coupled to the charge pump device for filtering the control signal to generate a reference signal; a controllable oscillator for generating the synthesized signal according to the reference signal; and a switch device coupled to the controllable oscillator for selectively coupling the controllable oscillator to the filtering device or a tuning reference signal. The calibration controller is coupled to the phase-locked loop device for generating the tuning reference signal and controlling the switch device. The first calibrator is coupled between the reference oscillating signal and the controllable oscillator and controlled by the calibration controller for tuning the controllable oscillator into a predetermined sub-band according to the reference oscillating signal and the synthesized signal when the switch device couples the controllable oscillator to the tuning reference signal of the calibration controller.

According to a second embodiment of the present invention, a signal generating apparatus is disclosed. The signal generating apparatus comprises a phase-locked loop device, a calibration controller, and a calibrator. The phase-locked loop device generates a synthesized signal, and the phase-locked loop device comprises a phase detector coupled to a reference oscillating signal for generating a detected signal according to the reference oscillating signal and the synthesized signal; a charge pump device coupled to the phase detector for generating a control signal according to the detected signal; a filtering device coupled to the charge pump device for filtering the control signal to generate a reference signal; a controllable oscillator for generating the synthesized signal according to the reference signal; and a switch device coupled to the controllable oscillator for selectively coupling the controllable oscillator to the filtering device or a tuning reference signal. The calibration controller is coupled to the phase-locked loop device for generating the tuning reference signal and controlling the switch device. The calibrator is coupled to the phase-locked loop device and controlled by the calibration controller for calibrating a loop gain of the phase-locked loop device when the switch device couples the controllable oscillator to the tuning reference signal of the calibration controller.

According to a third embodiment of the present invention, a signal generating method is disclosed. The signal generating method comprises the steps of: utilizing a phase-locked loop device to generate a synthesized signal, wherein the phase-locked loop device comprises a phase detector, coupled to a reference oscillating signal, for generating a detected signal according to the reference oscillating signal and the synthesized signal; a charge pump device, coupled to the phase detector, for generating a control signal according to the detected signal; a filtering device, coupled to the charge pump device, for filtering the control signal to generate a reference signal; a controllable oscillator for generating the synthesized signal according to the reference signal; and a switch device, coupled to the controllable oscillator, for selectively coupling the controllable oscillator to the filtering device or a tuning reference signal; generating the tuning reference signal and controlling the switch device; and tuning the controllable oscillator into a predetermined sub-band according to the reference oscillating signal and the synthesized signal when controlling the switch device to couple the controllable oscillator to the tuning reference signal.

According to a fourth embodiment of the present invention, a signal generating method is disclosed. The signal generating method comprises the steps of: utilizing a phase-locked loop device to generate a synthesized signal, the phase-locked loop device comprises: a phase detector, coupled to a reference oscillating signal, for generating a detected signal according to the reference oscillating signal and the synthesized signal; a charge pump device, coupled to the phase detector, for generating a control signal according to the detected signal; a filtering device, coupled to the charge pump device, for filtering the control signal to generate a reference signal; a controllable oscillator for generating the synthesized signal according to the reference signal; and a switch device, coupled to the controllable oscillator, for selectively coupling the controllable oscillator to the filtering device or a tuning reference signal; generating the tuning reference signal and controlling the switch device; and calibrating a loop gain of the phase-locked loop device when the switch device couples the controllable oscillator to the tuning reference signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a related art phase-locked loop circuit.

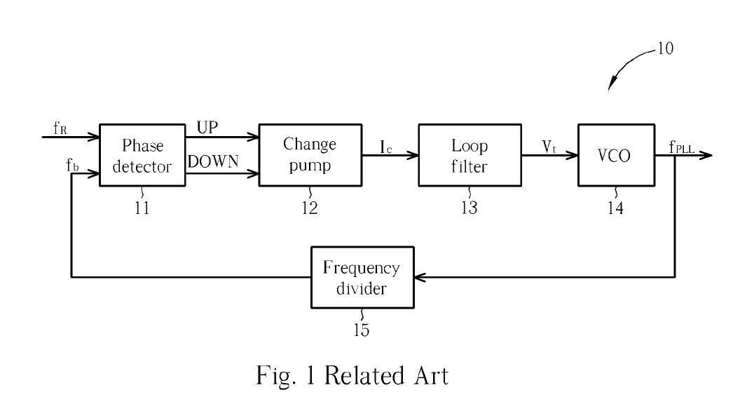

FIG. 2 is a diagram illustrating a signal generating apparatus according to an embodiment of the present invention.

FIG. 3 is a flowchart illustrating a signal generating method employed by the signal generating apparatus as shown in FIG. 2.

FIG. 4 is a diagram illustrating a signal generating apparatus according to a second embodiment of the present invention.

FIG. 5 is a flowchart illustrating a signal generating method employed by the signal generating apparatus as shown in FIG. 4.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

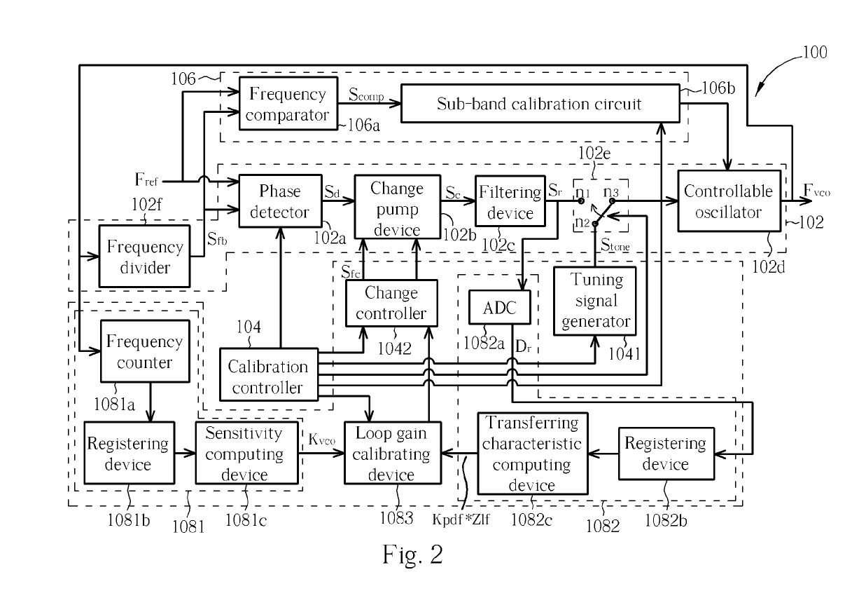

Please refer to FIG. 2. FIG. 2 is a diagram illustrating a signal generating apparatus 100 according to an embodiment of the present invention. The signal generating apparatus 100 comprises a phase-locked loop device 102, a calibration controller 104, a first calibrator 106, and a second calibrator 108. Please note that those skilled in this art will readily comprehend that the signal generating apparatus 100 can be implemented as a fast-locked-frequency PLL (Phase-locked loop) synthesizer with sub-band and loop gain calibration devices. The phase-locked loop device 102 comprises a phase detector 102a, a charge pump device 102b, a filtering device 102c, a controllable oscillator 102d, a switch device 102e, and a frequency divider 102f. The phase-locked loop device 102 generates a synthesized signal F_{VCO}. The phase detector 102a is coupled to a reference oscillating signal F_{ref} for generating a detected signal S_{d} according to the reference oscillating signal F_{ref} and the synthesized signal F_{VCO}. The charge pump device 102b is coupled to the phase detector 102a for generating a control signal S_{c} according to the detected signal S_{d}. The filtering device 102c is coupled to the charge pump device 102b for filtering the control signal S_{c} to generate a reference signal Sᵣ. The switch device 102e is coupled to the controllable oscillator 102d for selectively coupling the controllable oscillator 102d to the filtering device 102c or a tuning reference signal Sₜᵤₙₑ. The frequency divider 102f is coupled to the controllable oscillator 102d, the phase detector 102a, and the first calibrator 106 for dividing the synthesized signal F_{VCO} and outputting a resultant signal S_{fb} to the phase detector 102a and the first calibrator 106. The calibration controller 104 is coupled to the phase-locked loop device 102 for generating the tuning reference signal Sₜᵤₙₑ and controlling the switch device 102e. The first calibrator 106 is coupled between the reference oscillating signal F_{ref} and the controllable oscillator 102d and controlled by the calibration controller 104 for tuning the controllable oscillator 102d into a predetermined sub-band according to the reference oscillating signal F_{ref} and the synthesized signal F_{VCO} when the switch device 102e couples the controllable oscillator 102d to the tuning reference signal Sₜᵤₙₑ of the calibration controller 104. The second calibrator 108 is coupled to the phase-locked loop device 102 and controlled by the calibration controller 104 for calibrating a loop gain Gₗₒₒₚ of the phase-locked loop device 102 when the switch device 102e couples the controllable oscillator 102d to the tuning reference signal Sₜᵤₙₑ of the calibration controller 104.

Furthermore, the first calibrator 106 comprises a frequency comparator 106a and a sub-band calibration circuit 106b. The frequency comparator 106a is coupled to the resultant signal S_{fb} and the reference oscillating signal F_{ref} for comparing frequencies of the resultant signal S_{fb} and the reference oscillating signal F_{ref} to generate a compared signal S_{comp}. The sub-band calibration circuit 106b is coupled to the frequency comparator 106a for calibrating a sub-band of the controllable oscillator 102d according to the compared signal S_{comp}. The second calibrator 108 comprises a first operating device 1081, a second operating device 1082, and a loop gain calibrating device 1083. The first operating device 1081 is coupled to the synthesized signal F_{VCO} for measuring a sensitivity K_{VCO} of the controllable oscillator 102d. The second operating device 1082 is coupled to the filtering device 102c for measuring a transferring characteristic Kpdf*Zlf from the phase detector 102a to the filtering device 102c. The loop gain calibrating device 1083 is coupled to the charge pump device 102b for calibrating the loop gain Gₗₒₒₚ of the phase-locked loop device 102 according to the sensitivity Kvco and the transferring characteristic Kpdf*Zlf. The first operating device 1081 comprises a frequency counter 1081a, a registering device 1081b, and a sensitivity computing device 1081c. The frequency counter 1081a is coupled to the controllable oscillator 102d for counting frequency of the synthesized signal F_{VCO} to generate a plurality of counter values corresponding to a plurality of voltage levels of the tuning reference signal generated by the calibration controller 104 to the controllable oscillator 102d. The registering device 1081b is coupled to the frequency counter 1081a for registering the counter values. The sensitivity computing device 1081c is coupled to the registering device 1081b for determining the sensitivity Kvco of the controllable oscillator 102d according to the counter values and the voltage levels of the tuning reference signals. The second operating device 1082 comprises an analog-to-digital converter 1082a, a registering device 1082b, and a transferring characteristic computing device 1082c. The analog-to-digital converter 1082a is coupled to the filtering device 102c for generating a digital value Dr corresponding to the reference signal Sᵣ. The registering device 1082b is coupled to the analog-to-digital converter 1082a for registering the digital value Dᵣ. The transferring characteristic computing device 1082c is coupled to the registering device 1082b for determining the transferring characteristic Kpdf*Zlf according to the digital value Dᵣ.

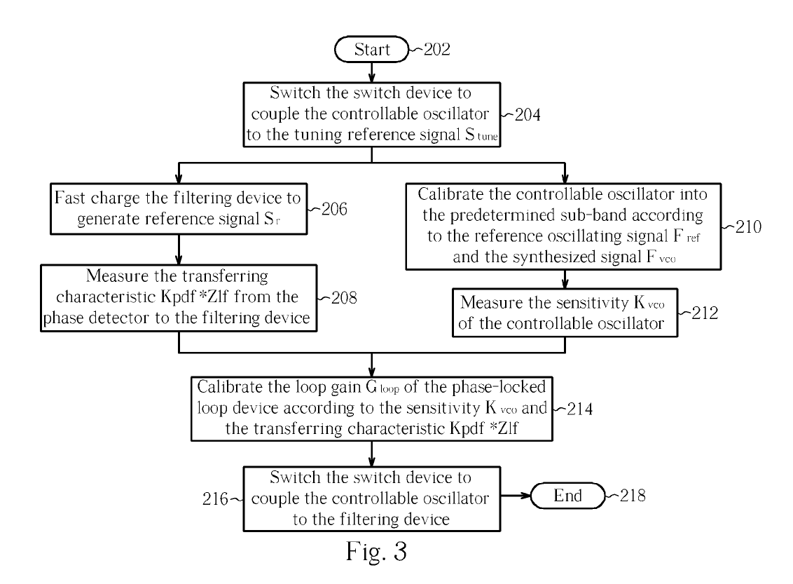

Please refer to FIG. 3. FIG. 3 is a flowchart illustrating a signal generating method employed by the signal generating apparatus 100 as shown in FIG. 2. In other words, the signal generating method is described through the fast-locked-frequency PLL (Phase-locked loop) synthesizer with sub-band and loop gain calibration devices. The signal generating method comprises the following steps:
Step 202: Start calibration;
Step 204: Switch the switch device 102e to couple the controllable oscillator 102d to the tuning reference signal Sₜᵤₙₑ;
Step 206: Fast charge the filtering device 102c to generate reference signal Sᵣ;
Step 208: Measure the transferring characteristic Kpdf*Zlf from the phase detector 102a to the filtering device 102c;
Step 210: Calibrate the controllable oscillator 102d into the predetermined sub-band according to the reference oscillating signal F_{ref} and the synthesized signal F_{VCO};
Step 212: Measure the sensitivity K_{VCO} of the controllable oscillator 102d;
Step 214: Calibrate the loop gain Gₗₒₒₚ of the phase-locked loop device 102 according to the sensitivity Kvco and the transferring characteristic Kpdf*Zlf;
Step 216: Switch the switch device 102e to couple the controllable oscillator 102d to the filtering device 102c;
Step 218: End calibration.

Please refer to FIG. 2 again. When the signal generating apparatus 100 of the present invention enters a calibration mode (step 202), the calibration controller 104 controls the switch device 102e to switch from a node N₁ into a node N₂, meaning that the node N₂ couples with a node N₃. In other words, the input node N₃ of the controllable oscillator 102d is coupled to the tuning reference signal Sₜᵤₙₑ, in which the tuning reference signal Sₜᵤₙₑ is controlled by the calibration controller 104. In the calibration mode, the signal generating apparatus 100 performs two calibrating operations by the controlling of the calibration controller 104, in which the two calibrating operations are the sub-band calibration of the controllable oscillator 102d and the loop-gain calibration of the phase-locked loop device 102. Please note that, in this embodiment, the signal generating apparatus 100 further comprises a tuning signal generator 1041 and a charge controller 1042. The tuning signal generator 1041 is coupled between the calibration controller 104 and the switch device 103e for generating the tuning reference signal Sₜᵤₙₑ, and the charge controller 1042 is coupled between the calibration controller 104 and the charge pump device 102b for generating a fast charging control signal S_{fc} to the charge pump device 102b. Accordingly, the calibration controller 104 controls the charge pump device 102b to transmit the fast charging control signal S_{fc} to the charge pump device 102b at the moment the calibration controller 104 switches the switch from the node N₁ into the node N₂. The fast charging control signal S_{fc} controls the charge pump device 102b to fast charge the filtering device 102c for generating an output voltage that is equal to the tuning reference signal Sₜᵤₙₑ at the node N₁ (step 206). In other words, when the signal generating apparatus 100 of the present invention enters the calibration mode, the filtering device 102c will open the loop of the phase-locked loop device 102. In order to let the loop-gain calibration of the phase-locked loop device 102 proceed properly, however, the voltage at the node N₁ should be maintained at the tuning reference signal Sₜᵤₙₑ. For example, the voltage at the node N₁ should be maintained at a voltage Vₜᵤₙₑ. In step 208, the calibration controller 104 disables the phase detector 102a to receive the resultant signal S_{fb} and the reference oscillating signal F_{ref}. Then, the calibration controller 104 controls the phase detector 102a to output the detected signal S_{d} for controlling the charge pump device 102b. After the filtering device 102c filters the control signal S_{c} generated by the charge pump device 102b, the analog-to-digital converter 1082a converts the reference signal Sᵣ into digital data and the registering device 1082b registers the digital data. Then, the transferring characteristic computing device 1082c measures the transferring characteristic Kpdf*Zlf from the phase detector 102a to the filtering device 102c according to the digital data. Please note that, as the generation of the transferring characteristic Kpdf*Zlf is well known by those skilled in this art, the detailed description is omitted here for brevity.

On the other hand, in the sub-band calibration (step 210), the calibration controller 104 sets the tuning signal generator 1041 to output a predetermined voltage at the node N₃, in which the predetermined voltage can be a center voltage of the tuning range of the controllable oscillator 102d, but this is not a limitation of the present invention. Then, the sub-band calibration circuit 106b sets the controllable oscillator 102d to oscillate under a predetermined condition, in which the predetermined condition should correspond to a sub-band F_{sub} of the controllable oscillator 102d. However, due to process variation, such as temperature effect, the output of the controllable oscillator 102d may not generate the required sub-band F_{sub} under the predetermined condition, and therefore the frequency comparator 106a compares frequencies of the resultant signal S_{fb} and the reference oscillating signal F_{ref} to generate the compared signal S_{comp} to the sub-band calibration circuit 106b. Then, the sub-band calibration circuit 106b calibrates the controllable oscillator 102d until the required sub-band F_{sub} is generated by the controllable oscillator 102d. Please note that, as the calibration of the controllable oscillator 102d is well known by those skilled in this art, the detailed description is omitted here for brevity.

Accordingly, in step 212, the calibration controller 104 controls the tuning signal generator 1041 to output the tuning reference signal Sₜᵤₙₑ in order to calibrate the sensitivity K_{VCO} of the controllable oscillator 102d. Please note that, in step 212, the tuning reference signal Sₜᵤₙₑ is a voltage difference ΔV at the node N₂, in which the voltage difference ΔV is the difference in voltage between voltage levels Vₜᵤₙₑ₁ and V_{tune 2}, i.e. ΔV=V_{tune 2}-Vₜᵤₙₑ₁. In other words, the tuning signal generator 1041 generates the voltages Vₜᵤₙₑ₁ and Vₜᵤₙₑ₂ in the calibration mode. Therefore, the voltage Vₜᵤₙₑ₁ is the control voltage of the sub-band F_{sub} of the controllable oscillator 102d, and the voltage Vₜᵤₙₑ₂ is the control voltage of a synthesized frequency F_{sub}+Δf differing in frequency by an amount Δf with the sub-band F_{sub} of the controllable oscillator 102d. Accordingly, the sensitivity Kvco of the controllable oscillator 102d under the sub-band F_{sub} can be obtained by dividing the frequency difference Δf by the difference voltage ΔV, i.e. Kvco=Δf/ΔV. Please note that the frequency counter 1081a is utilized for measuring the frequencies of the synthesized signal F_{VCO} and the synthesized frequency F_{sub}+Δf to generate the respective counter values. The respective counter values are then registered in the registering device 1081b. Then, the sensitivity K_{VCO} of the controllable oscillator 102d can be obtained by the sensitivity computing device 1081c. Accordingly, the loop gain calibrating device 1083 calibrates the loop gain Gₗₒₒₚ of the phase-locked loop device 102 by utilizing the charge controller 1042 to adjust the charge/pump current of the charge pump device 102b (step 214). Similarly, as the calibration of the loop gain Gₗₒₒₚ through adjusting the charge/pump current is well known by those skilled in this art, the detailed description is omitted here for brevity. When the calibration mode is finished, the calibration controller 104 controls the switch device 102e to switch back from the node N₂ into the node N₁, which means that the node N₁ is coupled with a node N₃. In other words, the input node N₃ of the controllable oscillator 102d is coupled to the node N₁ of the filtering device 102c, and the signal generating apparatus 100 enters a normal mode.

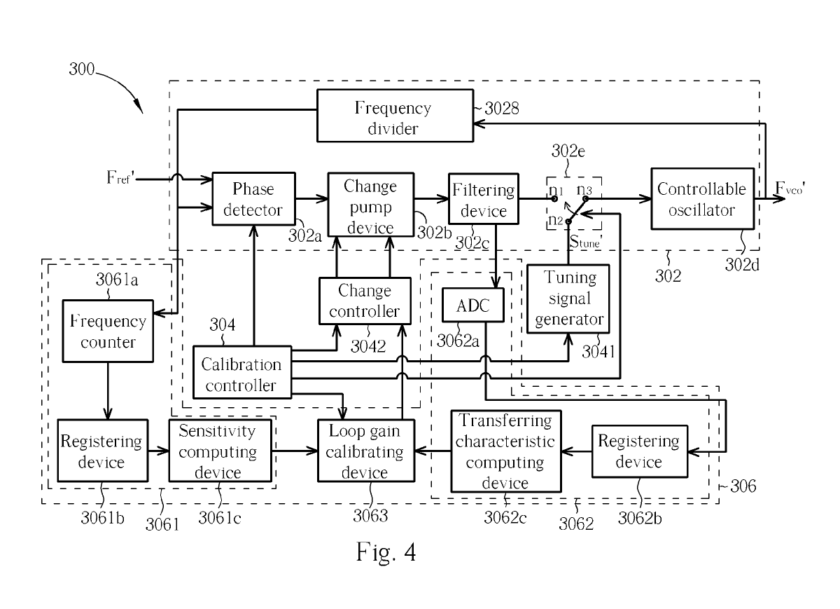

Please refer to FIG. 4. FIG. 4 is a diagram illustrating a signal generating apparatus 300 according to a second embodiment of the present invention. The signal generating apparatus 300 comprises a phase-locked loop device 302, a calibration controller 304, and a calibrator 306. Please note that those skilled in this art will readily understand that the signal generating apparatus 300 can be implemented as a fast-locked-frequency PLL (Phase-locked loop) synthesizer with loop gain calibration devices. The phase-locked loop device 302 comprises a phase detector 302a, a charge pump device 302b, a filtering device 302c, a controllable oscillator 302d, a switch device 302e, and a frequency divider 302f. The calibration controller 304 is coupled to the phase-locked loop device 302 for generating the tuning reference signal Sₜᵤₙₑ′ and controlling the switch device 302e. The calibrator 306 comprises a first operating device 3061, a second operating device 3062, and a loop gain calibrating device 3063. The first operating device 3061 comprises a frequency counter 3061a, a registering device 3061b, and a sensitivity computing device 3061c. The second operating device 3062 comprises an analog-to-digital converter 3062a, a registering device 3062b, and a transferring characteristic computing device 3062c. Furthermore, the signal generating apparatus 300 further comprises a tuning signal generator 3041 and a charge controller 3042. Please note that the operation of the signal generating apparatus 300 is similar to that of the signal generating apparatus 100, the difference being that the signal generating apparatus 100 performs the sub-band calibration whereas the signal generating apparatus 300 does not. Thus, those skilled in this art will readily understand the operation of the signal generating apparatus 300 after reading the disclosure of the first embodiment.

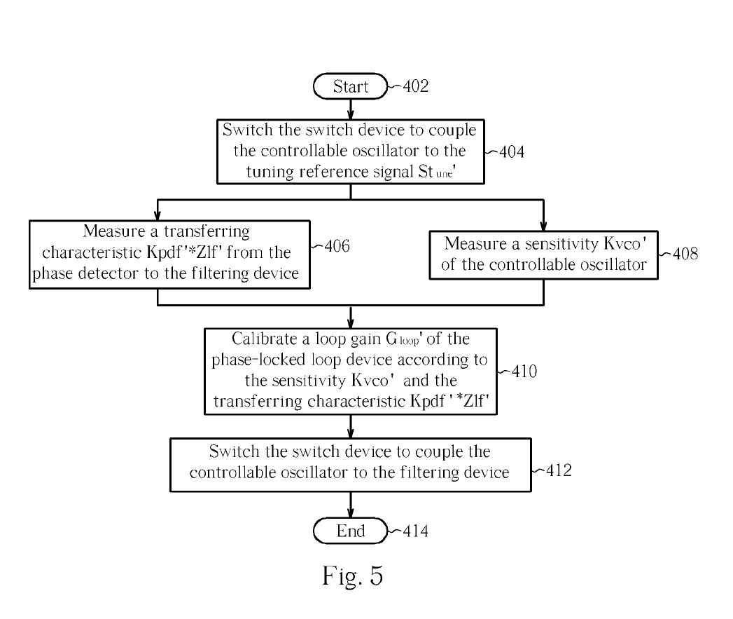

Please refer to FIG. 5. FIG. 5 is a flowchart illustrating a signal generating method employed by the signal generating apparatus 300 as shown in FIG. 4. In other words, the signal generating method is described through the fast-locked-frequency PLL (Phase-locked loop) synthesizer with loop gain calibration devices. The signal generating method comprises the following steps:
Step 402: Start calibration;
Step 404: Switch the switch device 302e to couple the controllable oscillator 302d to the tuning reference signal Sₜᵤₙₑ′;
Step 406: Measure a transferring characteristic Kpdf′*Zlf′ from the phase detector 302a to the filtering device 302c;
Step 408: Measure a sensitivity Kvco′ of the controllable oscillator 302d;
Step 410: Calibrate a loop gain Gₗₒₒₚ′ of the phase-locked loop device 302 according to the sensitivity Kvco′ and the transferring characteristic Kpdf′*Zlf′;
Step 412: Switch the switch device 302e to couple the controllable oscillator 302d to the filtering device 302c;
Step 414: End calibration.

Similar to the step 208, in step 406, the transferring characteristic Kpdf′*Zlf′ is measured by the transferring characteristic computing device 3062c. In step 408, the sensitivity K_{VCO}′ is measured by the first operating device 3061. In step 410, the loop gain calibrating device 3063 calibrates the loop gain Gₗₒₒₚ′ of the phase-locked loop device 302 by utilizing the charge controller 3042 to adjust the charge/pump current of the charge pump device 302b.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal generating apparatus, comprising:
a phase-locked loop device, for generating a synthesized signal, comprising:
a phase detector, coupled to a reference oscillating signal, for generating a detected signal according to the reference oscillating signal and the synthesized signal;
a charge pump device, coupled to the phase detector, for generating a control signal according to the detected signal;
a filtering device, coupled to the charge pump device, for filtering the control signal to generate a reference signal;
a controllable oscillator, for generating the synthesized signal according to the reference signal; and
a switch device, coupled to the controllable oscillator, for selectively coupling the controllable oscillator to the filtering device or a tuning reference signal;
a calibration controller, coupled to the phase-locked loop device, for generating the tuning reference signal and controlling the switch device;
a first calibrator, coupled between the reference oscillating signal and the controllable oscillator and controlled by the calibration controller, for tuning the controllable oscillator into a predetermined sub-band according to the reference oscillating signal and the synthesized signal when the switch device couples the controllable oscillator to the tuning reference signal of the calibration controller; and
a second calibrator, coupled to the phase-locked loop device and controlled by the calibration controller, for calibrating a loop gain of the phase-locked loop device when the switch device couples the controllable oscillator to the tuning reference signal of the calibration controller.

2. The signal generating apparatus of claim 1, further comprising:
a frequency divider, coupled to the controllable oscillator, the phase detector, and the first calibrator, for dividing the synthesized signal and outputting a resultant signal to the phase detector and the first calibrator.

3. The signal generating apparatus of claim 2, wherein the first calibrator comprises:
a frequency comparator, coupled to the resultant signal and the reference oscillating signal, for comparing frequencies of the resultant signal and the reference oscillating signal to generate a compared signal; and
a sub-band calibration circuit, coupled to the frequency comparator, for calibrating a sub-band of the controllable oscillator according to the compared signal.

4. The signal generating apparatus of claim 1, wherein the second calibrator comprises:
a first operating device, coupled to the synthesized signal, for measuring a sensitivity of the controllable oscillator;
a second operating device, coupled to the filtering device, for measuring a transferring characteristic from the phase detector to the filtering device; and
a loop gain calibrating device, coupled to the charge pump device, for calibrating the loop gain of the phase-locked loop device according to the sensitivity and the transferring characteristic.

5. The signal generating apparatus of claim 4, wherein the first operating device comprises:
a frequency counter, coupled to the controllable oscillator, for counting frequency of the synthesized signal to generate a plurality of counter values corresponding to a plurality of voltage levels of the tuning reference signal generated by the calibration controller to the controllable oscillator;
a registering device, coupled to the frequency counter, for registering the counter values; and
a sensitivity computing device, coupled to the registering device, for determining the sensitivity of the controllable oscillator according to the counter values and the voltage levels of the tuning reference signals.

6. The signal generating apparatus of claim 4, wherein the second operating device comprises:
an analog-to-digital converter, coupled to the filtering device, for generating a digital value corresponding to the reference signal;
a registering device, coupled to the analog-to-digital converter, for registering the digital value; and
a transferring characteristic computing device, coupled to the registering device, for determining the transferring characteristic according to the digital value.

7. A signal generating apparatus, comprising:
a phase-locked loop device, for generating a synthesized signal, comprising:
a phase detector, coupled to a reference oscillating signal, for generating a detected signal according to the reference oscillating signal and the synthesized signal;
a charge pump device, coupled to the phase detector, for generating a control signal according to the detected signal;
a filtering device, coupled to the charge pump device, for filtering the control signal to generate a reference signal;
a controllable oscillator, for generating the synthesized signal according to the reference signal; and
a switch device, coupled to the controllable oscillator, for selectively coupling the controllable oscillator to the filtering device or a tuning reference signal;
a calibration controller, coupled to the phase-locked loop device, for generating the tuning reference signal and controlling the switch device; and
a calibrator, coupled to the phase-locked loop device and controlled by the calibration controller, for calibrating a loop gain of the phase-locked loop device when the switch device couples the controllable oscillator to the tuning reference signal of the calibration controller.

8. The signal generating apparatus of claim 7, further comprising:
a frequency divider, coupled to the controllable oscillator, the phase detector, and the first calibrator, for dividing the synthesized signal and outputting a resultant signal to the phase detector and the first calibrator.

9. The signal generating apparatus of claim 8, wherein the calibrator comprises:
a first operating device, coupled to the synthesized signal, for measuring a sensitivity of the controllable oscillator;
a second operating device, coupled to the filtering device, for measuring a transferring characteristic from the phase detector to the filtering device; and
a loop gain calibrating device, coupled to the charge pump device, for calibrating the loop gain of the phase-locked loop device according to the sensitivity and the transferring characteristic.

10. The signal generating apparatus of claim 9, wherein the first operating device comprises:
a frequency counter, coupled to the controllable oscillator, for counting frequency of the synthesized signal to generate a plurality of counter values corresponding to a plurality of voltage levels of the tuning reference signal generated by the calibration controller to the controllable oscillator;
a registering device, coupled to the frequency counter, for registering the counter values; and
a sensitivity computing device, coupled to the registering device, for determining the sensitivity of the controllable oscillator according to the counter values and the voltage levels of the tuning reference signals.

11. The signal generating apparatus of claim 9, wherein the second operating device comprises:
an analog-to-digital converter, coupled to the filtering device, for generating a digital value corresponding to the reference signal;
a registering device, coupled to the analog-to-digital converter, for registering the digital value; and
a transferring characteristic computing device, coupled to the registering device, for determining the transferring characteristic according to the digital value.

12. A signal generating method, comprising:
(a) utilizing a phase-locked loop device to generating a synthesized signal, wherein the phase-locked loop device comprises:
a phase detector, coupled to a reference oscillating signal, for generating a detected signal according to the reference oscillating signal and the synthesized signal;
a charge pump device, coupled to the phase detector, for generating a control signal according to the detected signal;
a filtering device, coupled to the charge pump device, for filtering the control signal to generate a reference signal;
a controllable oscillator, for generating the synthesized signal according to the reference signal; and
a switch device, coupled to the controllable oscillator, for selectively coupling the controllable oscillator to the filtering device or a tuning reference signal;
(b) generating the tuning reference signal and controlling the switch device;
(c) tuning the controllable oscillator into a predetermined sub-band according to the reference oscillating signal and the synthesized signal when controlling the switch device to couple the controllable oscillator to the tuning reference signal; and
(d) calibrating a loop gain of the phase-locked loop device when controlling the switch device to couple the controllable oscillator to the tuning reference signal.

13. The signal generating method of claim 12, further comprising:
dividing the synthesized signal and outputting a resultant signal to the phase detector.

14. The signal generating method of claim 13, wherein the step (c) comprises:
comparing frequencies of the resultant signal and the reference oscillating signal to generate a compared signal; and
calibrating a sub-band of the controllable oscillator according to the compared signal.

15. The signal generating method of claim 12, wherein the step (d) comprises:
(e) measuring a sensitivity of the controllable oscillator;
(f) measuring a transferring characteristic from the phase detector to the filtering device; and
(g) calibrating the loop gain of the phase-locked loop device according to the sensitivity and the transferring characteristic.

16. The signal generating method of claim 15, wherein the step (e) comprises:
counting frequency of the synthesized signal to generate a plurality of counter values corresponding to a plurality of voltage levels of the tuning reference signal generated in step (b) to the controllable oscillator;
registering the counter values; and
determining the sensitivity of the controllable oscillator according to the counter values and the voltage levels of the tuning reference signals.

17. The signal generating method of claim 15, wherein the step (f) comprises:
generating a digital value corresponding to the reference signal;
registering the digital value; and
determining the transferring characteristic according to the digital value.

18. A signal generating method, comprising:
(a) utilizing a phase-locked loop device to generate a synthesized signal, the phase locked loop comprising:
a phase detector, coupled to a reference oscillating signal, for generating a detected signal according to the reference oscillating signal and the synthesized signal;
a charge pump device, coupled to the phase detector, for generating a control signal according to the detected signal;
a filtering device, coupled to the charge pump device, for filtering the control signal to generate a reference signal;
a controllable oscillator, for generating the synthesized signal according to the reference signal; and
a switch device, coupled to the controllable oscillator, for selectively coupling the controllable oscillator to the filtering device or a tuning reference signal;
(b) generating the tuning reference signal and controlling the switch device; and
(c) when the switch device couples the controllable oscillator to the tuning reference signal, measuring a sensitivity of the controllable oscillator and a transferring characteristic from the phase detector to the filtering device to calibrate a loop gain of the phase-locked loop device according to the sensitivity and the transferring characteristic.

19. The signal generating method of claim 18, further comprising:
dividing the synthesized signal and outputting a resultant signal to the phase detector and the first calibrator.

20. The signal generating method of claim 18, wherein the step (d) comprises:
counting frequency of the synthesized signal to generate a plurality of counter values corresponding to a plurality of voltage levels of the tuning reference signal generated in the step (b) to the controllable oscillator;
registering the counter values; and
determining the sensitivity of the controllable oscillator according to the counter values and the voltage levels of the tuning reference signals.

21. The signal generating method of claim 18, wherein the step (e) comprises:
generating a digital value corresponding to the reference signal;
registering the digital value; and
determining the transferring characteristic according to the digital value.
